(19) United States
(12) Patent Application Publication
(10) Pub. No.: US 2015/0325747 A1
(43) Pub. Date: Nov. 12, 2015

(54) SEMICONDUCTOR LIGHT EMITTING ELEMENT

(71) Applicant: KABUSHIKI KAISHA TOSHIBA, Tokyo (JP)

(72) Inventors: Satoshi Mitsugi, Kawasaki Kanagawa (JP); Hiroshi Katsuno, Komatsu Ishikawa (JP); Jumpei Tajima, Koganei Tokyo (JP)

(21) Appl. No.: 14/642,610

(22) Filed: Mar. 9, 2015

(30) Foreign Application Priority Data
May 12, 2014 (JP) 2014-099105

(51) Int. Cl. H01L 33/38; H01L 33/00

(52) U.S. Cl. CPC H01L 33/38; H01L 33/005; H01L 2933/0016

(57) ABSTRACT

According to one embodiment, a semiconductor light emitting element includes a stacked body, a first electrode, a second electrode and a first layer. The stacked body includes a first semiconductor layer, a second semiconductor layer and a light emitting layer. The first semiconductor layer has a first conductivity type. The second semiconductor layer has a second conductivity type. The light emitting layer is provided between the first semiconductor layer and the second semiconductor layer. The first electrode is connected to the first semiconductor layer. The first electrode includes a line-shaped portion and a bent portion. The line-shaped portion is linked to the bent portion. The second electrode is connected to the second semiconductor layer. The first layer is provided between part of the first semiconductor layer and the bent portion of the first electrode.

### CROSS-REFERENCE TO RELATED APPLICATIONS

This application is based upon and claims the benefit of priority from Japanese Patent Application No. 2014-099105, filed on May 12, 2014; the entire contents of which are incorporated herein by reference.

### FIELD

Embodiments described herein relate generally to a semiconductor light emitting element.

### BACKGROUND

A semiconductor light emitting element such as LED (light emitting diode) includes a semiconductor layer including a light emitting layer as well as a p-electrode and an n-electrode. In the semiconductor light emitting element, the p-electrode is formed on one surface of the semiconductor layer, and the n-electrode is formed on the other surface of the semiconductor layer. Alternatively, the p-electrode and the n-electrode are formed on one surface of the semiconductor layer. Improvement in light emission efficiency is desired in such a semiconductor light emitting element.

### BRIEF DESCRIPTION OF THE DRAWINGS

FIGS. 1A to 1C are schematic views illustrating a semiconductor light emitting element according to a first embodiment;

FIG. 2 is a schematic sectional view showing a variation according to the first embodiment;

FIGS. 3A to 3C are schematic views illustrating a semiconductor light emitting element and its characteristics of a comparative example;

FIGS. 4A to 4C are schematic plan views illustrating a semiconductor light emitting element and its characteristics according to the variation of the first embodiment;

FIG. 5 illustrates a result of simulating the characteristics of the semiconductor light emitting elements of FIGS. 3A to 3C and FIGS. 4A to 4C;

FIGS. 6A and 6B are schematic views illustrating a semiconductor light emitting element according to a second embodiment;

FIG. 7 is a schematic view illustrating an alternative semiconductor light emitting element according to the second embodiment;

FIGS. 8A and 8B are reference views illustrating a semiconductor light emitting element and its characteristics;

FIGS. 9A and 9B illustrate the semiconductor light emitting element and its characteristics according to the second embodiment;

FIG. 10 illustrates a result of simulating the characteristics of the semiconductor light emitting elements of FIGS. 8A and 8B and FIGS. 9A and 9B; and

FIGS. 11A to 11C show the arrangement of the current block layer.

### DETAILED DESCRIPTION

According to one embodiment, a semiconductor light emitting element includes a stacked body, a first electrode, a second electrode and a first layer. The stacked body includes a first semiconductor layer, a second semiconductor layer and a light emitting layer. The first semiconductor layer has a first conductivity type. The second semiconductor layer has a second conductivity type. The light emitting layer is provided between the first semiconductor layer and the second semiconductor layer. The first electrode is connected to the first semiconductor layer. The first electrode includes a line-shaped portion and a bent portion. The line-shaped portion is linked to the bent portion. The second electrode is connected to the second semiconductor layer. The first layer is provided between part of the first semiconductor layer and the bent portion of the first electrode.

Embodiments of the invention will now be described with reference to the drawings.

The drawings are schematic or conceptual. The relationship between the thickness and the width of each portion, and the size ratio between the portions, for instance, are not necessarily identical to those in reality. Furthermore, the same portion may be shown with different dimensions or ratios depending on the figures.

In the present description and the drawings, components similar to those described previously with reference to earlier figures are labeled with like reference numerals, and the detailed description thereof is omitted appropriately.

### First Embodiment

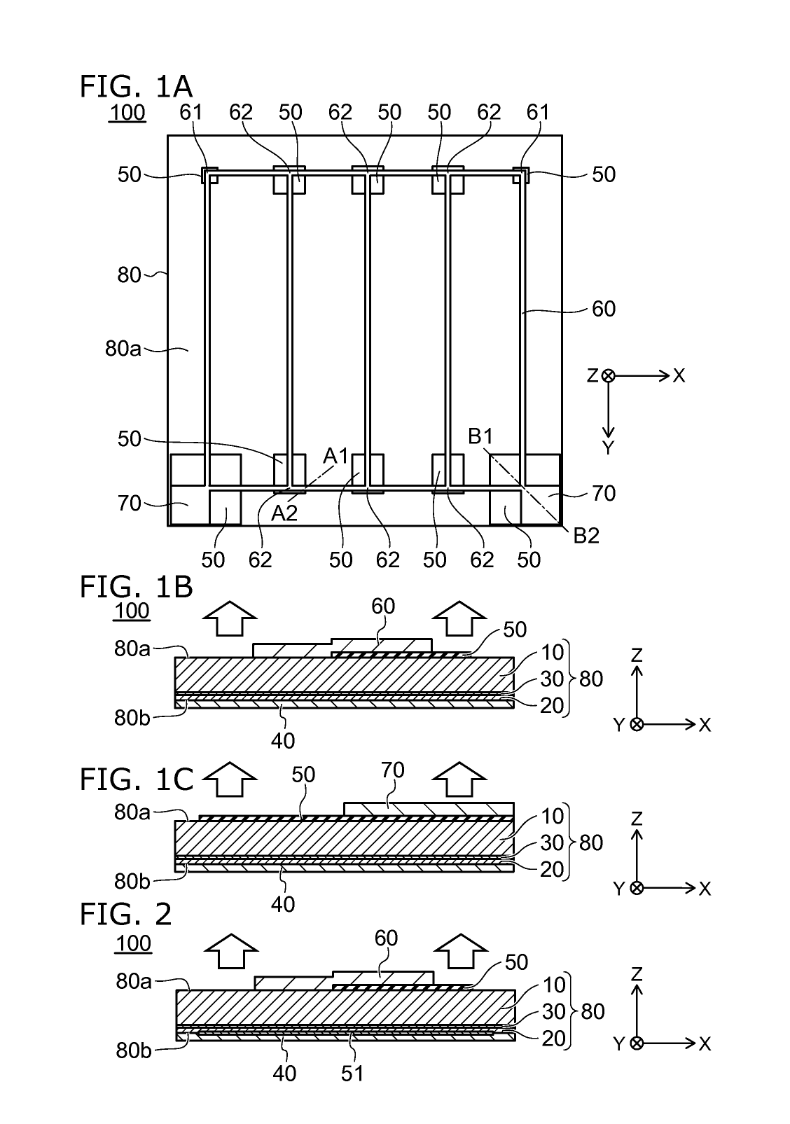

FIGS. 1A to 1C are schematic views illustrating a semiconductor light emitting element of a first embodiment.

FIG. 1A is a schematic plan view of the semiconductor light emitting element 100. FIG. 1B is a schematic sectional view taken along line A1-A2 of FIG. 1A. FIG. 1C is a schematic sectional view taken along line B1-B2 of FIG. 1A.

As shown in FIGS. 1A to 1C, the semiconductor light emitting element 100 according to the first embodiment includes an n-type semiconductor layer 10 (first semiconductor layer of a first conductivity type), a p-type semiconductor layer 20 (second semiconductor layer of a second conductivity type), a light emitting layer 30 provided between the n-type semiconductor layer 10 and the p-type semiconductor layer 20, a p-electrode 40 (second electrode) provided on the surface of the p-type semiconductor layer 20 on the opposite side from the formation surface of the light emitting layer 30, a current block layer 50 (first layer) provided on the surface of the n-type semiconductor layer 10 on the opposite side from the formation surface of the light emitting layer 30, an n-electrode 60 (first electrode) provided on the n-type semiconductor layer 10 and the current block layer 50, and an n-electrode pad 70 (electrode pad). A semiconductor layer 80 (stacked body) includes the n-type semiconductor layer 10, the p-type semiconductor layer 20, and the light emitting layer 30. The semiconductor layer 80 has a first surface 80a and a second surface 80b. The first surface 80a is a surface on the opposite side from the second surface 80b. The multilayer including the n-type semiconductor layer 10, the p-type semiconductor layer 20, the light emitting layer 30, and the current block layer 50 is provided in the semiconductor light emitting element 100.

The direction from the p-electrode 40 toward the n-electrode 60 is referred to as Z-axis direction. One direction perpendicular to the Z-axis direction is referred to as X-axis direction. The direction perpendicular to the X-axis direction and perpendicular to the Z-axis direction is referred to as Y-axis direction. Thus, the direction from the n-type semiconductor layer 10 toward the p-type semiconductor layer 20 is the -Z-axis direction (first direction).

The semiconductor light emitting element 100 is a light emitting diode (LED) made of GaN-based nitride semiconductor. The semiconductor light emitting element 100 has a thin-film structure. The semiconductor light emitting element of the thin-film structure has a structure in which a semiconductor layer grown on a growth substrate is transferred to e.g. a support substrate different from the growth substrate. Furthermore, the semiconductor light emitting element 100 has a vertical conduction structure with the p-electrode 40 provided on the second surface 80b side and the n-electrode 60 provided on the first surface 80a side. In the following, with regard to the semiconductor light emitting element, the vertical conduction thin-film structure may also be referred to as VTF (vertical thin-film) structure.

The n-electrode 60 provided in the semiconductor light emitting element 100 has a narrow wire electrode structure including a line-shaped portion. Alternatively, the p-electrode 40 may be shaped like a line. That is, one of the p-electrode 40 and the n-electrode 60 includes a line-shaped portion. The electrode may be shaped like a frame, comb, lattice, zigzag, or a combination of some of them.

The n-type semiconductor layer 10 is an n-type GaN layer. The p-type semiconductor layer 20 is a p-type GaN layer. The light emitting layer 30 is a semiconductor layer of e.g. nitride semiconductor. The light emitting layer 30 has a multiple quantum well structure. The thickness in the Z-axis direction of the semiconductor layer 80 is approximately 1-4 μm.

The p-electrode 40 is made of e.g. silver (Ag). Part of the light emitted from the light emitting layer 30 is reflected by the p-electrode 40 and extracted in the Z-axis direction.

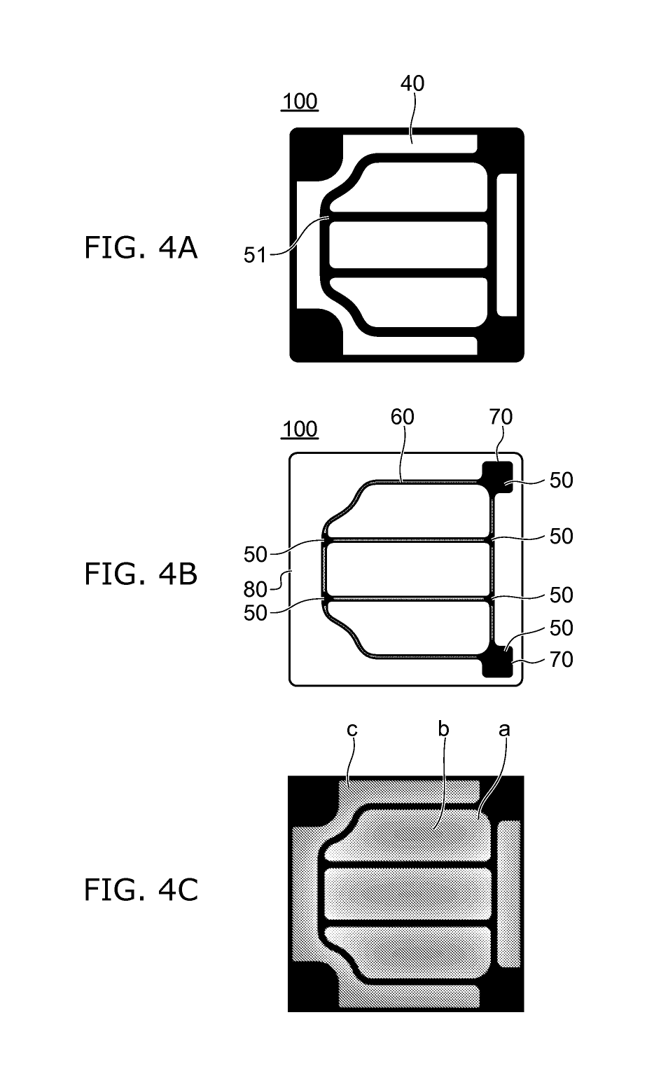

The n-electrode 60 is made of e.g. aluminum (Al). The thickness in the Z-axis direction of the n-electrode 60 is 200 nm or more and 400 nm or less. The n-electrode 60 is shaped like a plurality of frames linked continuously in one direction on the first surface 80a. The n-electrode 60 is shaped like e.g. a vertical lattice. The shape of the n-electrode 60 includes a corner part 61 and a crossing part 62. The corner part 61 includes a portion in which part of the line-shaped portion of the n-electrode 60 is bent on the first surface 80a. In this practical example, as shown in FIGS. 1A to 1C, the corner part 61 is a portion having a certain angle. For instance, the corner part 61 is a portion provided generally perpendicularly (another example of the bent shape is shown in e.g. FIGS. 4A to 4C). The corner part 61 includes a bent portion (first bent portion). The crossing part 62 is a portion in which the line-shaped portions of the n-electrode 60 cross near the periphery of the first surface 80a. The crossing part 62 is a T-shaped portion. Furthermore, the crossing part 62 includes the bent portion (second bent portion) which is bent generally perpendicularly. The crossing part 62 may include the bent portion which is bent as shown in FIGS. 4A to 4C.

The line-shaped portion is a portion which has a generally linear shape. For instance, as shown in FIGS. 1A to 1C, the line-shaped portion is a portion of the n-electrode 60 which has a generally linear shape.

The bent portion is a portion which is bent at a certain angle. For instance, as shown in FIGS. 1A to 1C, the bent portion is a portion of the n-electrode 60 linked to the line-shaped portion and bent generally perpendicularly. Alternatively, as shown in FIGS. 4A to 4C, the bent portion may be a portion of the n-electrode 60 bent with a gradual curvature. The bent portion may be a portion having a prescribed curvature radius.

The n-electrode pad 70 has a generally quadrangular shape and is provided near the corner of the first surface 80a. The n-electrode pad 70 is electrically connected to the n-electrode 60.

The current block layer 50 is an insulating layer or a high resistance layer. The current block layer 50 includes e.g. a material including a dielectric, a material including a non-contact metal (a metal not in contact with the semiconductor layer 80 at low resistance in relation to work function, or a metal having high resistance due to interface barrier), or a material having a higher resistance by two or more orders of magnitude than the material of the n-electrode 60.

The current block layer 50 may be a semi-insulating layer or a semiconductor layer. Alternatively, the current block layer 50 may be a metal compound having a high contact resistance with respect to the n-electrode 60. The current block layer 50 can include an arbitrary material for suppressing current concentration of the n-electrode 60. The current block layer 50 can be provided on the basis of the thickness and the material of the current block layer 50.

The material including a dielectric includes silicon oxide (SiO₂), silicon nitride (Si₃N₄), silicon oxynitride (SiON), lithium fluoride (LiF), aluminum oxide (Al₂O₃), aluminum nitride (AlN), gallium nitride (GaN), hafnium oxide (HfO₂), zirconium dioxide (ZrO₂), titanium oxide (TiO₂), or other oxides, nitrides, fluorides, or a mixture including them. In view of light extraction efficiency, the dielectric has a high optical transparency and a refractive index comparable to or lower than that of the semiconductor layer 80. A lower refractive index is more desirable. The dielectric may be formed like a foam or sponge to decrease the average refractive index. The current block layer 50 functions as a total internal reflection (TIR) mirror. This suppresses loss of light caused by the n-electrode 60. The thickness in the Z-axis direction of the current block layer 50 is preferably λ/2n or more. However, in the case where the optical absorption of the dielectric is not negligible or the case where the effect of TIR is not expected, the thickness is preferably 1 nm or more and λ/8n or less. At 1 nm or less, the tunnel current may be significant in some dielectrics. The range from λ/8n to λ/2n is not desirable because of the increase of optical absorption by the n-electrode 60. Here, λ, is the wavelength of light, and n is the refractive index of the dielectric at λ.

Preferably, the material including a non-contact metal has high optical reflectance. However, depending on the combination of materials, the material works well even at a thickness of approximately 0.5 nm. At a thickness of 5 nm or less, the optical characteristic of the n-electrode material is dominant, and hence the optical characteristic of the metal itself forming the current block layer 50 is not significant. In the VTF structure, the GaN layer formed in the initial phase of crystal growth may be used as the current block layer 50. Alternatively, the first surface 80a in contact with the n-electrode 60 may be previously inactivated by processing such as plasma processing, radical processing, or ion processing to prevent contact. In these cases, the thickness of the current block layer is not defined.

As shown in FIGS. 1A and 1B, the current block layer 50 is provided between the corner part 61 of the n-electrode 60 and the n-type semiconductor layer 10 and between the crossing part 62 and the n-type semiconductor layer 10. The current block layer 50 is provided between the bent portion of the n-electrode 60 and the n-type semiconductor layer 10. Furthermore, the current block layer 50 is provided between the n-electrode pad 70 and the n-type semiconductor layer 10.

The current block layer 50 is provided in an arbitrary shape such as a rectangular shape.

FIG. 2 is a schematic sectional view showing a variation according to the first embodiment.

In the variation, a current block layer 51 (second layer) is provided between the p-electrode 40 and the p-type semiconductor layer 20. The current block layer 51 is provided on the second surface 80b of the semiconductor layer 80 so as to be opposed to the crossing part 62 of the n-electrode 60. In plan view in the Z-axis direction, the current block layer 51 has a larger area than the crossing part 62. The variation includes the current block layer 51 in addition to the configuration of the semiconductor light emitting element 100 of FIGS. 1A to 1C. The sectional view of FIG. 2 corresponds to the sectional view of FIG. 1B.

The current block layer 51 may be provided on the second surface 80b directly below the n-electrode pad 70 so as to correspond to the n-electrode pad 70 having low light extraction efficiency.

According to this embodiment, in the semiconductor light emitting element 100, the current block layer 50 is provided between the corner part 61 or the crossing part 62 of the n-electrode 60 and the n-type semiconductor layer 10, or between the n-electrode pad 70 and the n-type semiconductor layer 10. This can suppress the increase of wiring resistance, and suppress current concentration. Thus, a semiconductor light emitting element with highly uniform light emission is provided by achieving highly uniform current spreading.

In the following, investigation results led to the aforementioned condition are described.

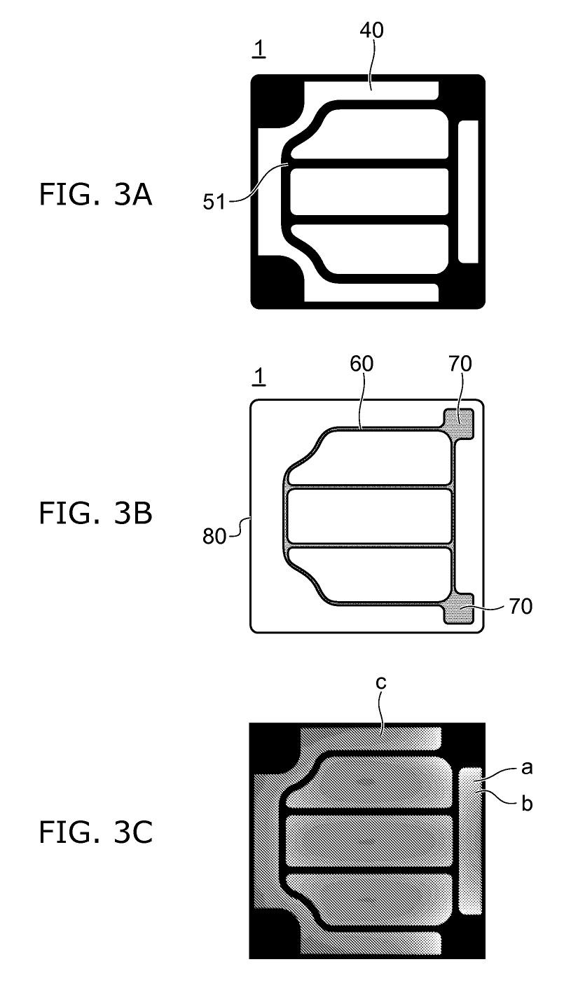

FIGS. 3A to 3C are schematic views illustrating a semiconductor light emitting element and its characteristics of a comparative example.

FIGS. 4A to 4C are schematic plan views illustrating a semiconductor light emitting element and its characteristics according to the variation of the first embodiment.

Here, FIGS. 3A and 4A show schematic plan views as viewed from the n-electrode side. Two electrodes not connected to the n-electrode 60 are shown on the left side of the figure. These two electrodes are not described or shown in the first embodiment, but may be provided in the semiconductor light emitting element 100 according to the first embodiment. In the semiconductor light emitting elements 1, 100 under comparison and investigation, part of the corner part 61 has a shape bent with a gradual curvature.

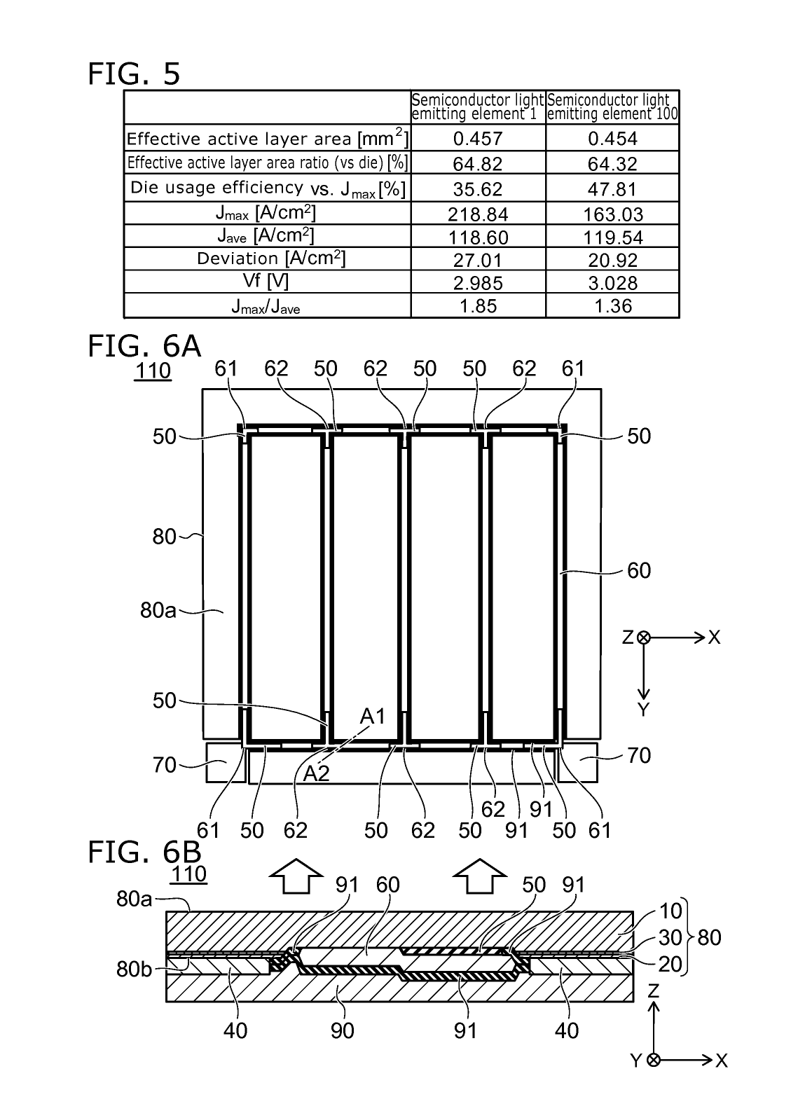

FIG. 5 illustrates a result of simulating the characteristics of the semiconductor light emitting elements of FIGS. 3A to 3C and FIGS. 4A to 4C.

The semiconductor light emitting element 1 of the comparative example shown in FIGS. 3A to 3C is different from the semiconductor light emitting element 100 of the variation in not including the current block layer 51. The rest of the stacked structure is the same. FIG. 3B is a schematic plan view as viewed from the p-electrode 40 side. FIG. 3C shows the current density distribution of the semiconductor light emitting element 1.

FIGS. 4A to 4C are schematic plan views of the semiconductor light emitting element 100 of the variation. FIG. 4B is a schematic plan view as viewed from the p-electrode 40 side. FIG. 4C shows the current density distribution of the semiconductor light emitting element 100. As shown in FIG. 4B, the current block layer 50 is T-shaped. The current block layer 50 is provided between the n-electrode pad 70 and the n-type semiconductor layer 10 so as to be opposed to the n-electrode pad 70. The shape of the current block layer 50 corresponds to the shape of the electrode pad 70.

FIG. 5 shows numerical values regarding the current characteristics of the semiconductor light emitting element 1 and numerical values regarding the current characteristics of the semiconductor light emitting element 100. The current characteristics are (1) effective active layer area (mm²), (2) ratio of effective active layer area with reference to die (%), (3) die usage efficiency versus maximum current density (%), (4) maximum current density Jₘₐₓ (A/cm²), (5) average current density Jₐᵥₑ (A/cm²), (6) current deviation (A/cm²), (7) driving voltage Vf (V), and (8) ratio Jₘₐₓ/Jₐᵥₑ of maximum current density Jₘₐₓ to average current density Jₐᵥₑ.

Here, the die refers to the shape and size of the LED chip cut out from the wafer, and includes also the electrode pad and the non-emitting region at the outer periphery. The item (1) is the area of the active area actually injected with the current and contributing to light emission. The item (3) is a value calculated as the correlation coefficient between the current density distribution and the shape of the die, and defined to be 100% when the current is distributed uniformly throughout the die. The item (5) is a value obtained by dividing the injected current by the effective active layer area. The item (6) is a value calculated as the standard deviation (σ) of the frequency distribution of the current density.

The distribution of current density shown in FIGS. 3C and 4C, and the current characteristics shown in FIG. 5, are simulation results under the assumption that the semiconductor light emitting element 1 and the semiconductor light emitting element 100 have a size of 0.8 mm square, and that a current of 550 mA is applied to this chip.

In FIGS. 3C and 4C, the current density with the maximum current density being 100% is 75% in region a, 65% in region b, and 50% (60% in FIG. 4C) or more in region c. The portion with a lighter shade indicates a higher current density. The distribution of current density is shown by monotone shade. A higher current density is indicated by a lighter shade, and a lower current density is indicated by a darker shade. By comparison between the region distribution of FIGS. 3C and 4C, the current concentrates around the n-electrode pad 70 in FIG. 3C. In FIG. 5, the maximum current density Jₘₐₓ of the semiconductor light emitting element 100 is significantly decreased. This means that the neighborhood of the n-electrode pad 70 intensively emits light in the structure of the semiconductor light emitting element 1 of FIG. 3C, whereas light emission occurs entirely and uniformly in the structure of the semiconductor light emitting element 100 of FIG. 4C. Thus, it is considered that the uniformity of current spreading is higher in the semiconductor light emitting element 100.

On the other hand, the driving voltage of the semiconductor light emitting element 100 is higher by approximately 0.043 V than the driving voltage of the semiconductor light emitting element 1. In view of light emission efficiency, the current density efficiency of the light emitting layer 30 may be considered as a current characteristic.

In a semiconductor light emitting element, the material of the n-electrode and the p-electrode is a metal having low optical transmittance. Thus, in order to efficiently extract light, at least one of the n-electrode and the p-electrode is formed in a line shape so as to minimize prevention of light extraction. The method of forming an electrode by routing a line-shaped portion, and the method of arranging a plurality of electrodes having a line shape, are widely used from the viewpoint of design and manufacturing.

For instance, in the case of a gallium nitride-based semiconductor light emitting element used in white LED illumination and the like, it is difficult to make the resistance of the p-type semiconductor layer and the contact resistance of the p-electrode lower than the resistance of the n-type semiconductor layer and the contact resistance of the n-electrode. Thus, in order to prevent the decrease of light emission efficiency due to resistance increase, the area of the p-electrode is increased, and the area of the n-electrode is decreased. In this case, the electrode including a line-shaped portion is the n-electrode.

In LED, the current flows easily near the electrode, but less easily at a position more remote from the electrode. The degree of spreading of the current like this is defined by the value called current spreading length (Ls). The current spreading length is obtained by experimentally or analytically calculating the current spreading around an electrode shaped like a straight line. The current spreading length varies with the characteristics, thickness, injected current density, temperature and the like of the semiconductor layer. In a practical LED chip, the current spreading length is approximately 50-300 μm.

The current spreading length is affected by the current density. Thus, current concentration occurs in a portion from which a plurality of electrodes originate, and a portion near the current injection source. In a semiconductor light emitting element having a narrow wire electrode structure with a complex arrangement of n-electrodes including a line-shaped portion, current concentration is likely to occur e.g. near the corner part of the n-electrode, near the crossing part of the n-electrode, and near the n-electrode pad. The neighborhood of the n-electrode pad has low electrical resistance. Thus, a high density current is likely to flow therein. The internal angle of the corner part and the crossing part of the n-electrode is smaller than 180 degrees, such as approximately 90 degrees. Thus, in plan view, the n-electrode is arranged so as to surround part of the surface of the semiconductor layer on the internal angle side. The inflow current increases in such arrangement. Current concentration occurs in a relatively small region having a dimension of approximately Ls or less.

In recent semiconductor light emitting elements, the brightness has been made higher, and the size has been made smaller. In the case where such a semiconductor light emitting element locally has high current density, the semiconductor light emitting element may be destroyed by current concentration. Furthermore, in the case where such a semiconductor light emitting element locally has high current density, unevenness occurs in the light emission of the light emitting layer. This decreases the light emission efficiency.

It is difficult to make the current injection uniform to eliminate current concentration only by means of the arrangement of electrodes including a line-shaped portion. The current concentration can be eliminated by arranging electrodes at an equal spacing of approximately the current spreading length. However, it is difficult in design to arrange electrodes at an equal spacing. This imposes constraints on the arrangement of electrodes and decreases the degree of freedom of the design.

There is known a method for eliminating current concentration using a nonmetallic electrode in combination. In this method, a transparent electrode of e.g. ITO (indium tin oxide) is placed on all or part of the light extraction surface, and an electrode including a line-shaped portion is supplementarily used. This method ameliorates current concentration. However, in the case where the transparent electrode has the effect of absorbing or reflecting light, the light extraction efficiency decreases. If the transparency of the transparent electrode is increased to increase the light extraction efficiency, the carrier density decreases. The decrease of carrier density results in increasing the driving voltage. This decreases the wall-plug efficiency (WPE).

There is also known a method for eliminating current concentration using a planar electrode and a through via electrode. However, the planar electrode cannot be provided with a sufficient thickness. Furthermore, the through via electrode cannot be provided with a sufficient area because the insulating region placed between the planar electrode and the through via electrode has a large area. Thus, the driving voltage is increased. This decreases the wall-plug efficiency. The process for forming a through via electrode is complex. Furthermore, in view of the structure of the semiconductor light emitting element, it is difficult to apply these electrode structures to the semiconductor light emitting element of the VTF structure.

According to this embodiment, the current block layer 50 is provided between the corner part 61 and the crossing part 62 of the n-electrode 60 on one hand and the n-type semiconductor layer 10 on the other, and between the n-electrode pad 70 and the n-type semiconductor layer 10. This can suppress the increase of wiring resistance in the n-electrode 60 including a line-shaped portion to suppress current concentration. In the semiconductor light emitting element 100, highly uniform light emission is achieved by achieving highly uniform current spreading.

Furthermore, there is no need to consider the change of the electrode pattern when designing the electrode of the semiconductor light emitting element. The current spreading can be improved by suppressing the increase of driving voltage. This provides a semiconductor light emitting element having high light emission efficiency by efficiently using the entirety of the light emitting layer.

Furthermore, as shown in FIGS. 1A to 1C, the current block layer 50 is provided between the corner part 61 of the n-electrode 60 and the n-type semiconductor layer 10 and between the crossing part 62 and the n-type semiconductor layer 10. In such case, by comparison between parts of the n-electrode 60 which is and is not contacted to the current block layer 50, a distance in the Z-axis direction between the contacted part of the n-electrode 60 and the semiconductor layer 80 is longer than a distance in the Z-axis direction between the non-contacted part of the n-electrode 60 and the semiconductor layer 80. This suppresses current concentration of the part of the n-electrode 60 contacted to the current block layer 50.

This embodiment provides a semiconductor light emitting element having improved light emission efficiency.

### Second Embodiment

FIGS. 6A and 6B are schematic views illustrating a semiconductor light emitting element of a second embodiment.

FIG. 6A is a schematic plan view of the semiconductor light emitting element 110. FIG. 6B is a schematic sectional view taken along line A1-A2 of FIG. 6A.

As shown in FIGS. 6A and 6B, the semiconductor light emitting element 110 according to the second embodiment includes an n-type semiconductor layer 10, a p-type semiconductor layer 20, a light emitting layer 30 provided between the n-type semiconductor layer and the p-type semiconductor layer, a p-electrode 40 provided on the surface of the p-type semiconductor layer 20 on the opposite side from the formation surface of the light emitting layer 30, a current block layer 50 provided on the surface of the n-type semiconductor layer 10 on the same side as the formation surface of the light emitting layer 30, an n-electrode 60 provided on the n-type semiconductor layer 10 and the current block layer 50, an n-electrode pad 70, a support layer 90, and an insulating layer 91. A semiconductor layer 80 includes the n-type semiconductor layer 10, the p-type semiconductor layer 20, and the light emitting layer 30. The semiconductor layer 80 has a first surface 80a and a second surface 80b. The first surface 80a is a surface on the opposite side from the second surface 80b. The multilayer including the n-type semiconductor layer 10, the p-type semiconductor layer 20, the light emitting layer 30, and the current block layer 50 is provided in the semiconductor light emitting element 110.

The semiconductor light emitting element 110 has a thin-film structure. The semiconductor light emitting element 110 is a semiconductor light emitting element having a lateral conduction structure in which the p-electrode 40 and the n-electrode 60 are provided on the same surface side of the semiconductor layer 80. The p-electrode 40 and the n-electrode 60 are provided on the second surface 80b side. In the following, with regard to the semiconductor light emitting element, the lateral conduction thin-film structure may also be referred to as LTF (lateral thin-film) structure.

The n-electrode 60 provided in the semiconductor light emitting element 110 includes a line-shaped portion (narrow wire electrode structure). The p-electrode 40 is electrically connected to the p-type semiconductor layer 20. The light emitted from the light emitting layer 30 is reflected by the p-electrode 40 and extracted in the Z-axis direction.

The n-electrode 60 is electrically connected to the n-type semiconductor layer 10. As described above, the shape of the n-electrode 60 includes a line-shaped portion. By the n-electrode 60, a plurality of frame bodies are continuously formed on the second surface 80b. The n-electrode 60 includes a corner part 61 and a crossing part 62. The corner part 61 is a portion in which the line-shaped portion of the n-electrode 60 is provided generally perpendicularly near the corner of the second surface 80b. The line-shaped portion of the n-electrode 60 may be provided so as to be bent near the corner of the second surface 80b. The crossing part 62 is a portion in which the line-shaped portions of the n-electrode 60 cross each other near the periphery of the second surface 80b.

The n-electrode pad 70 has a generally quadrangular shape and is provided near the end part of the semiconductor layer 80. The n-electrode pad 70 is electrically connected to the n-electrode 60. The n-electrode pad 70 is in contact with the n-electrode 60. This allows the n-electrode pad 70 to be electrically connected to the n-electrode 60.

The support layer 90 is configured as e.g. a back metal, solder buried layer, bonding layer or the like. The support layer 90 is provided on the p-electrode 40 and the insulating layer 91. The insulating layer 91 is provided between the support layer 90 on one hand and the n-type semiconductor layer 10 and the p-type semiconductor layer 20 on the other. Furthermore, in the X-axis direction, the insulating layer 91 is provided between the p-electrode 40 and the n-electrode 60 for insulation between the two electrodes. The insulating layer 91 is made of a dielectric that can be used for the current block layer 50, such as silicon oxide (SiO₂) and silicon nitride (SiN).

The current block layer 50 is provided between the corner part 61 and the crossing part 62 of the n-electrode 60 on one hand and the n-type semiconductor layer 10 on the other.

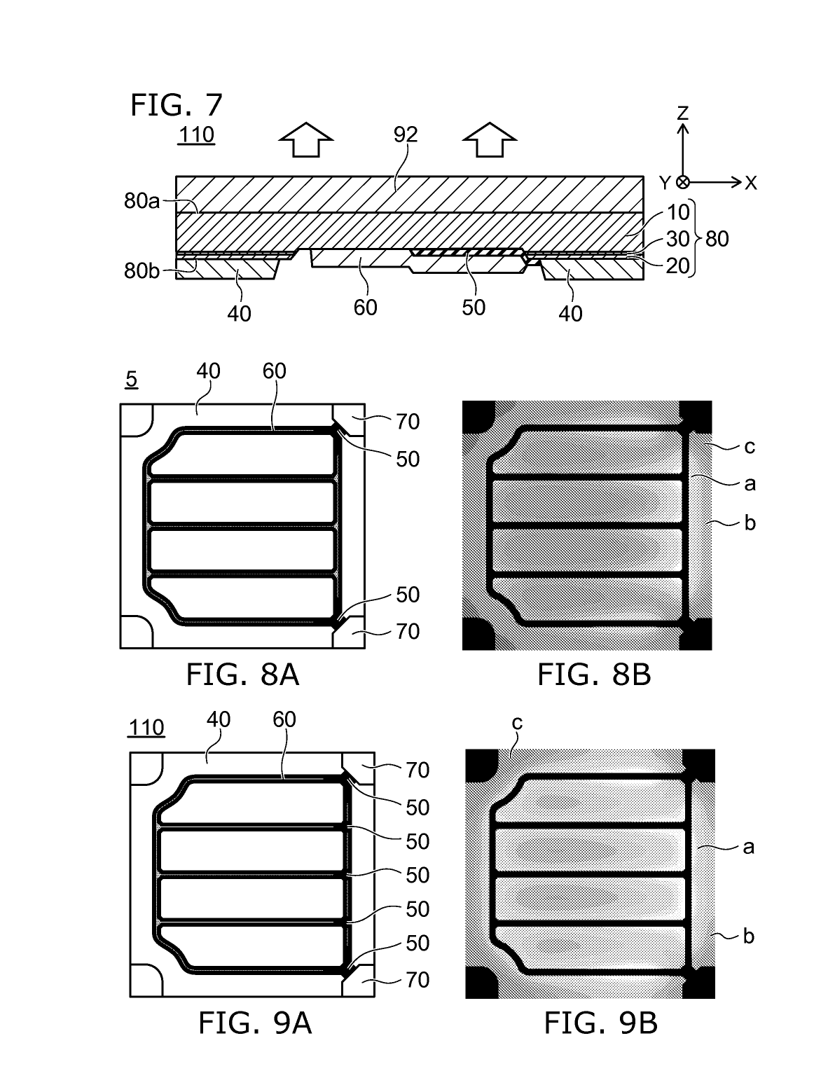

FIG. 7 is a schematic sectional view illustrating an alternative semiconductor light emitting element according to the second embodiment.

The semiconductor light emitting element 110 of FIG. 7 is different from the semiconductor light emitting element 110 of FIGS. 6A and 6B in that a substrate 92 is provided on the semiconductor layer 80 and that the support layer 90 and the insulating layer 91 are not provided. That is, the semiconductor light emitting element 110 of FIG. 7 is a semiconductor light emitting element of the FC (flip chip) structure or FU (face up) structure. The sectional view of FIG. 7 corresponds to the sectional view of FIG. 6B. The semiconductor light emitting element 110 of FIG. 7 is generally identical to the semiconductor light emitting element 110 of FIGS. 6A and 6B except that a substrate 92 is provided on the semiconductor layer 80 and that the support layer 90 and the insulating layer 91 are not provided.

As shown in FIG. 7, in the semiconductor light emitting element 110, the current block layer 50 is provided between the n-electrode 60 and the n-type semiconductor layer 10 near the corner part 61 and the crossing part 62 of the n-electrode 60. Furthermore, in the direction perpendicular to the stacking direction, the current block layer 50 is provided between the p-electrode 40 and the n-electrode 60.

According to this embodiment, in the semiconductor light emitting element 100, the current block layer 50 is provided between the n-electrode 60 and the n-type semiconductor layer 10. This can suppress the increase of wiring resistance in the n-electrode 60 including a line-shaped portion, and suppress current concentration. Thus, a semiconductor light emitting element with highly uniform light emission is provided by achieving highly uniform current spreading.

In the following, investigation results led to the aforementioned condition are described.

In the following, the support layer 90, the insulating layer 91, the p-electrode 40, the n-electrode 60, the current block layer 50, and the semiconductor layer 80 are stacked in the Z-axis direction. The semiconductor layer 80 includes the n-type semiconductor layer 10, the p-type semiconductor layer 20, and the light emitting layer 30. The n-electrode 60 is electrically connected to the n-electrode pad 70. The characteristics of the semiconductor light emitting element 110 of the LTF structure having such a stacked structure are evaluated by simulation.

FIGS. 8A and 8B are reference views illustrating a semiconductor light emitting element and its characteristics.

FIGS. 9A and 9B illustrate the semiconductor light emitting element and its characteristics according to the second embodiment.

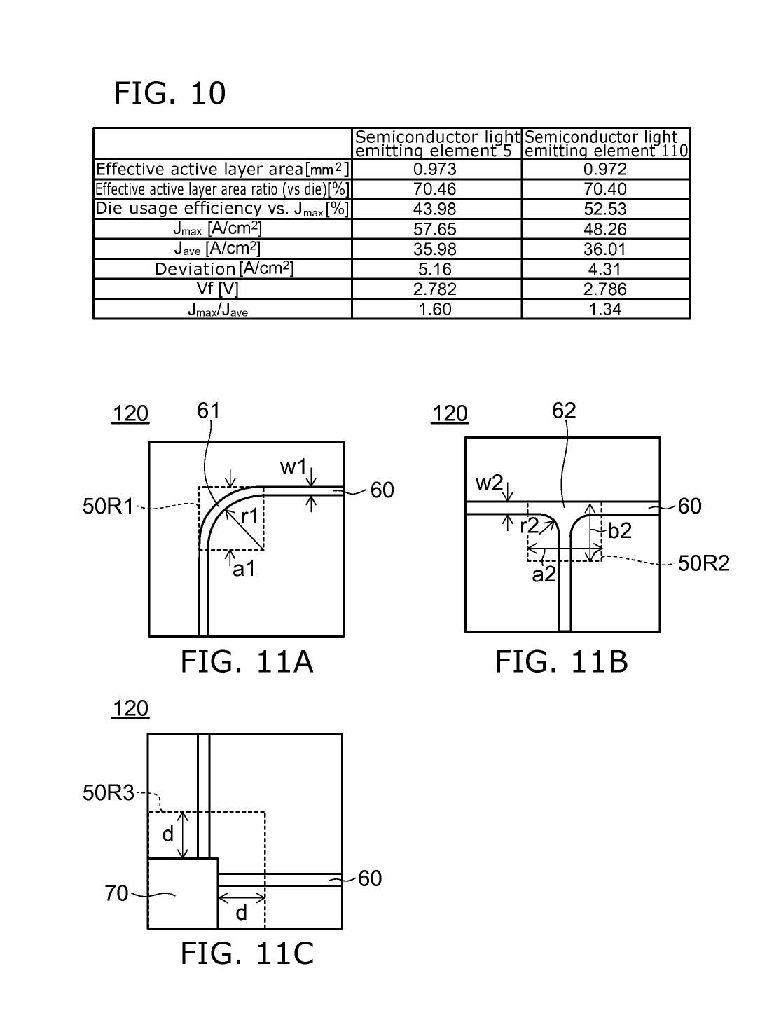

FIG. 10 illustrates a result of simulating the characteristics of the semiconductor light emitting elements of FIGS. 8A and 8B and FIGS. 9A and 9B.

In the semiconductor light emitting element 5 of FIGS. 8A and 8B, the support layer 90, the insulating layer 91, the p-electrode 40, the n-electrode 60, the current block layer 50, and the semiconductor layer 80 are stacked in the Z-axis direction. The semiconductor layer 80 includes the n-type semiconductor layer 10, the p-type semiconductor layer 20, and the light emitting layer 30. The n-electrode 60 is electrically connected to the n-electrode pad 70. FIG. 8A is a schematic plan view of the semiconductor light emitting element 5 of the LTF structure including such a stacked body. The current block layer 50 is provided between the n-electrode 60 and the n-type semiconductor layer 10 near the corner part of the n-electrode 60 (near the n-electrode pad 70). FIG. 8B shows the current density distribution of the semiconductor light emitting element 5.

FIG. 9A is a schematic plan view of the semiconductor light emitting element 110. FIG. 9B shows the current density distribution of the semiconductor light emitting element 110. As shown in FIG. 9A, the current block layer 50 is provided between the n-electrode 60 and the n-type semiconductor layer 10 near the corner part 61 of the n-electrode 60 (near the n-electrode pad 70). Furthermore, the current block layer 50 is provided between the n-electrode pad 70 and the n-type semiconductor layer 10 near the crossing part of the n-electrode 60. That is, the semiconductor light emitting element 110 of FIGS. 9A and 9B is different from the semiconductor light emitting element 5 of FIGS. 8A and 8B in that the current block layer 50 is provided near the crossing part of the n-electrode 60.

Like FIG. 5, FIG. 10 shows numerical values regarding the current characteristics of the semiconductor light emitting element 5 and numerical values regarding the current characteristics of the semiconductor light emitting element 110. The current characteristics are (1) effective active layer area (mm²), (2) ratio of effective active layer area with reference to die (%), (3) die usage efficiency versus maximum current density (%), (4) maximum current density Jₘₐₓ (A/cm²), (5) average current density Jₐᵥₑ (A/cm²), (6) current deviation (A/cm²), (7) driving voltage Vf (V), and (8) ratio Jₘₐₓ/Jₐᵥₑ of maximum current density Jₘₐₓ to average current density Jₐᵥₑ.

The distribution of current density shown in FIGS. 8B and 9B, and the current characteristics shown in FIG. 10, are simulation results under the assumption that the semiconductor light emitting element 5 and the semiconductor light emitting element 110 are chips of the LTF structure having a size of 1.1 mm, and that a current of 350 mA is applied to this chip.

FIGS. 8B and 9B show region a, region b, and region c. With the maximum current density being 100%, region a, region b, and region c indicate the region in which the current density is 80%, 65%, and 50% or more, respectively. The portion with a lighter shade indicates a higher current density. The distribution of current density is shown by monotone shade. A higher current density is indicated by a lighter shade, and a lower current density is indicated by a darker shade. By comparison between the region distribution of FIGS. 8B and 9B, the current concentrates around the crossing part of the n-electrode 60 in FIG. 8B. In FIG. 10, the maximum current density Jₘₐₓ of the semiconductor light emitting element 110 is significantly decreased. This means that the crossing part of the n-electrode 60 intensively emits light in the structure of the semiconductor light emitting element 5 of FIG. 8B, whereas light emission occurs entirely and uniformly in the structure of the semiconductor light emitting element 110 of FIG. 9B. Thus, it is considered that the uniformity of current spreading is higher in the semiconductor light emitting element 110.

According to this embodiment, the current block layer 50 is provided between the n-electrode 60 and the n-type semiconductor layer 10 near the corner part 61 and the crossing part 62 of the n-electrode 60. This can suppress the increase of wiring resistance in the n-electrode 60 including a line-shaped portion to suppress current concentration. In the semiconductor light emitting element 110, highly uniform light emission is achieved by achieving highly uniform current spreading. Furthermore, there is no need to consider the change of the electrode pattern when designing the electrode of the semiconductor light emitting element. The current spreading can be improved by suppressing the increase of driving voltage. This provides a semiconductor light emitting element having high light emission efficiency by efficiently using the entirety of the light emitting layer.

This embodiment provides a semiconductor light emitting element having improved light emission efficiency.

FIGS. 11A to 11C show the arrangement of the current block layer.

In the following, the range in which the current block layer 50 is arranged in the semiconductor light emitting element 120 is described.

FIG. 11A is a schematic plan view of the semiconductor light emitting element 120 enlarging the neighborhood of the corner part 61 in the case where the corner part 61 of the n-electrode 60 is bent. FIG. 11B is a schematic plan view of the semiconductor light emitting element 120 enlarging the neighborhood of the crossing part 62 of the n-electrode 60. FIG. 11C is a schematic plan view of the semiconductor light emitting element 120 enlarging the neighborhood of the n-electrode pad 70. The semiconductor light emitting element 120 is a semiconductor light emitting element of e.g. the VTF structure, LTF structure, FC structure, or FU structure.

In FIG. 11A, the region 50R1 surrounded with the dashed line is a region in which the current block layer 50 is arranged. The current block layer 50 is preferably formed directly above or directly below the n-electrode 60. The width of the n-electrode 60 is denoted by w1. The length of one side of the region 50R1 is denoted by a1. The curvature radius of the inner periphery of the corner part 61 (bent part) is denoted by r1. The current spreading length is denoted by Ls. Then, the current block layer 50 does not need to be arranged when r1>Ls. When r1≦Ls/2, the current block layer 50 is preferably arranged so as to satisfy the following condition formula (1).

w1+r1<a1<Ls/2 (1)

Under the condition of Ls/2<a1, the driving voltage increases. Thus, a1<Ls/2 is preferably satisfied if the driving voltage is not sufficiently low.

In FIG. 11B, the region 50R2 surrounded with the dashed line is a region in which the current block layer 50 is arranged. The width of the n-electrode 60 is denoted by w2. The length of one side of the region 50R2 is denoted by a2. The length of the other side of the region 50R2 is denoted by b2. The curvature radius of the inner periphery of the crossing part 62 is denoted by r2. The current spreading length is denoted by Ls. Then, the current block layer 50 is preferably arranged so as to satisfy the following condition formulas (2) and (3).

w2+2×r2<a2<Ls (2)

w2+r2<b2<Ls/2 (3)

Alternatively, the current block layer 50 is preferably arranged so as to satisfy the following condition formulas (4) and (5).

w2+2×r2<a2<Ls/2 (4)

w2+r2<b2<Ls (5)

In the design of the semiconductor light emitting element 120, the curvature radius r2 of the inner periphery of the crossing part 62 often satisfies the condition formula of r2<Ls/2. Here, in the case where the crossing part 62 is not T-shaped but shaped like a cross, both the lengths of one side and the other side of the region 50R2 are denoted by a2. Then, the current block layer 50 is preferably arranged so as to satisfy the following condition formula (6).

w2+2×r2<a2<Ls (6)

In FIG. 11C, the region 50R3 surrounded with the dashed line is a region in which the current block layer 50 is arranged. The n-electrode pad 70 has a large area. Thus, the overall current spreading is prone to imbalance. In the case where the semiconductor light emitting element 120 is a semiconductor light emitting element of the VTF structure, light generated near the n-electrode pad 70 is blocked by the n-electrode pad 70. This decreases the light emission efficiency. Thus, the current block layer 50 is preferably arranged in a wide range in addition to the entirety of the n-electrode pad 70.

In the case where light is diffused in the semiconductor layer, the efficiency of extracting light injected below the n-electrode pad 70 is low. The length obtained by subtracting one side of the n-electrode pad 70 from one side of the region 50R3 is denoted by d. The current spreading length is denoted by Ls. The diffusion distance of light is assumed to be approximately 20 times the thickness t of the semiconductor layer. Then, the current block layer 50 is preferably arranged so as to satisfy the following condition formula (7).

Max(Ls/2,20×t)<d<Max(Ls,20×t) (7)

In the case where the semiconductor light emitting element 120 is a semiconductor light emitting element of the LTF structure, the n-electrode pad 70 is not in contact with the semiconductor layer 80. Thus, there is no need to consider the diffusion length of light. Accordingly, the current block layer 50 is preferably arranged so as to satisfy the following condition formula (8).

Ls/2<d<Ls (8)

Current concentration is suppressed by arranging the current block layer 50 under the foregoing condition. Current concentration is likely to occur near the corner part 61 of the n-electrode 60, near the crossing part 62 of the n-electrode 60, and near the n-electrode pad 70. Furthermore, current concentration is more likely to occur in the crossing part 62 of the n-electrode 60 located near the n-electrode pad 70 than in the crossing part 62 located far from the n-electrode pad 70. Thus, the current block layer 50 is preferably arranged at a position where current concentration is likely to occur in view of the increase of the driving voltage.

Next, an example method for manufacturing the semiconductor light emitting element is described. The method for manufacturing a semiconductor light emitting element described below is a method for manufacturing the semiconductor light emitting element of the LTF structure.

An n-type semiconductor layer 10, a light emitting layer 30, and a p-type semiconductor layer 20 including nitride semiconductor are sequentially crystal grown on a growth substrate to form a semiconductor layer 80. The growth substrate is made of Si. Then, a metal film is formed by vacuum evaporation technique or sputtering technique. The metal film is patterned into a prescribed shape using e.g. a resist mask to form a p-electrode 40.

An opening is provided in the semiconductor layer 80. For instance, a resist is applied onto the p-type semiconductor layer 20, and patterned by e.g. photolithography.

Subsequently, part of the p-type semiconductor layer 20, the light emitting layer 30, and the n-type semiconductor layer 10 is etched by reactive ion etching (RIE). Thus, part of the n-type semiconductor layer 10 is exposed.

An insulating film is formed in the opening by plasma CVD (chemical vapor deposition) technique or sputtering technique. The insulating film is patterned into a prescribed shape using e.g. a resist mask to form a current block layer 50 and part of an insulating layer 91. Formation of the insulating film is preferably performed at a temperature of e.g. 300 degrees or less. This can suppress e.g. degradation of the reflectance of the p-electrode 40 and degradation of contact resistance.

An n-electrode 60 is formed so as to cover the exposed n-type semiconductor layer 10, the current block layer 50, and the insulating layer 91 by lift-off technique. Part of the insulating layer 91 is formed so as to cover the n-electrode 60. This insulating layer 91 is provided between the p-electrode 40 and the n-electrode 60. Subsequently, a support layer 90 and the like are stacked on the p-electrode 40 and the insulating layer 91.

The growth substrate is removed. More specifically, the growth substrate is removed by grinding and spin etching. Subsequently, an n-electrode pad 70 electrically connected to the n-electrode 60 is formed near the end part of the semiconductor layer 80.

The embodiments of the invention have been described above with reference to examples. However, the invention is not limited to these examples. For instance, any specific configurations of various components such as the p-electrode, n-electrode, p-type semiconductor layer, n-type semiconductor layer, light emitting layer, current block layer, n-electrode pad, insulating layer, support layer, and substrate included in the semiconductor light emitting element are encompassed within the scope of the invention as long as those skilled in the art can similarly practice the invention and achieve similar effects by suitably selecting such configurations from conventionally known ones.

Moreover, combinations of two or more components in the specific examples within a technically feasible range are also included in the scope of the invention as long as the spirit of the invention is included.

In addition, any semiconductor light emitting element, which those skilled in the art can carry out by making appropriate design modifications based on the semiconductor light emitting element described above as the embodiments of the invention, are also in the scope of the invention as long as the spirit of the invention is included.

Also, within the scope of principles of the invention, various changes and modifications will be readily made by those skilled in the art. Accordingly, it will be appreciated that such changes and modifications also fall within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Moreover, above-mentioned embodiments can be combined mutually and can be carried out.

What is claimed is:

1. A semiconductor light emitting element comprising:
a stacked body including a first semiconductor layer of a first conductivity type, a second semiconductor layer of a second conductivity type, and a light emitting layer provided between the first semiconductor layer and the second semiconductor layer;
a first electrode connected to the first semiconductor layer and including a line-shaped portion and a bent portion, the line-shaped portion being linked to the bent portion;
a second electrode connected to the second semiconductor layer; and
a first layer provided between part of the first semiconductor layer and the bent portion of the first electrode.

2. The element according to claim 1, wherein
the first electrode includes a plurality of frame-shaped portions linked continuously in one direction, and
the bent portion is part of a corner part of the frame-shaped portions.

3. The element according to claim 1, wherein
the first electrode includes a plurality of frame-shaped portions linked continuously in one direction, and
the bent portion is part of a crossing portion of the line-shaped portions.

4. The element according to claim 1, further comprising:
an electrode pad connected to the first electrode,
wherein the first layer is provided between part of the first semiconductor layer and the electrode pad.

5. The element according to claim 1, wherein the first electrode and the second electrode are provided on mutually opposite surfaces of the stacked body.

6. The element according to claim 5, further comprising a second layer provided between the second semiconductor layer and the second electrode.

7. The element according to claim 1, wherein the first electrode and the second electrode are provided on an identical surface of the stacked body.

8. The element according to claim 1, wherein the first layer is shaped like a rectangle as projected on a plane perpendicular to a first direction from the first semiconductor layer toward the second semiconductor layer.

9. The element according to claim 1, wherein the first layer is an insulating layer.

10. The element according to claim 1, wherein the first layer includes a material including a dielectric.

11. The element according to claim 10, wherein the dielectric is made of SiO₂, Si₃N₄, SiON, LiF, Al₂O₃, AlN, GaN, HfO₂, ZrO₂, TiO₂, or a mixture including them.

12. The element according to claim 1, wherein the first layer is formed by processing a surface of the first semiconductor layer by plasma processing, radical processing, or ion processing.

13. A semiconductor light emitting element comprising:
a stacked body including a first semiconductor layer of a first conductivity type, a second semiconductor layer of a second conductivity type, and a light emitting layer provided between the first semiconductor layer and the second semiconductor layer;
a first electrode connected to the first semiconductor layer and shaped like a line, part of the line shape being bent,
a second electrode connected to the second semiconductor layer; and
a first layer provided between part of the first semiconductor layer and the part of the line shape.

14. A semiconductor light emitting element comprising:
a stacked body including a first semiconductor layer of a first conductivity type, a second semiconductor layer of a second conductivity type, and a light emitting layer provided between the first semiconductor layer and the second semiconductor layer;
a first electrode connected to the first semiconductor layer and including a corner part and a crossing part, the corner part including a first bent portion, the crossing part including a second bent portion,
a second electrode connected to the second semiconductor layer; and
a first layer provided between part of the first semiconductor layer and at least one of the first and second bent portions.

15. The element according to claim 14, wherein the first layer is arranged on the basis of at least one of the curvature radius of the inner periphery of the corner part and the curvature radius of the inner periphery of the crossing part.

16. A method for manufacturing a semiconductor light emitting element, comprising:
forming an opening in part of a stacked body, the stacked body including a first semiconductor layer of a first conductivity type, a light emitting layer, and a second semiconductor layer of a second conductivity type stacked sequentially on a substrate;
forming a first layer by film formation in the opening; and
forming a first electrode including a line-shaped portion and a bent portion, the line-shaped portion being linked to the bent portion,
the first layer being located between part of the first semiconductor layer and the bent portion of the first electrode.

17. The method according to claim 16, further comprising:
forming a second electrode connected to the second semiconductor layer by forming a metal film on the stacked body.

18. The method according to claim 16, wherein
the first electrode includes a plurality of frame-shaped portions linked continuously in one direction, and
the bent portion is part of a corner part of the frame-shaped portions.

19. The method according to claim 16, wherein
the first electrode includes a plurality of frame-shaped portions linked continuously in one direction, and
the bent portion is part of a crossing portion of the line-shaped portions.

20. The method according to claim 16, wherein the first layer is shaped like a rectangle as projected on a plane perpendicular to a first direction from the first semiconductor layer toward the second semiconductor layer.

21. The method according to claim 16, wherein the first layer is an insulating layer.

22. The method according to claim 16, wherein the first layer includes a material including a dielectric.

23. The method according to claim 22, wherein the dielectric is made of SiO₂, Si₃N₄, SiON, LiF, Al₂O₃, AlN, GaN, HfO₂, ZrO₂, TiO₂, or a mixture including them.
